(19) United States
(12) Patent Application Publication
(10) Pub. No.: US 2026/0305396 A1
(43) Pub. Date: Oct. 1, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yi-Min FU, Taichung City (TW); Wen-Jung TSAI, Taichung City (TW); Jui-Cheng LIN, Taichung City (TW); Yu-Po WANG, Taichung City (TW)

(73) Assignee: SILICONWARE PRECISION INDUSTRIES CO., LTD., Taichung City (TW)

(21) Appl. No.: 19/287,065

(22) Filed: Jul. 31, 2025

(30) Foreign Application Priority Data
Mar. 26, 2025 (TW) 114111503

(51) Int. Cl. H01L 23/538; H01F 27/28; H01L 23/00; H01L 25/00; H01L 25/07

(52) U.S. Cl. CPC H10W 70/611; H01F 27/2804; H10W 90/00; H10W 90/401; H10W 90/10

(57) ABSTRACT

Provided are an electronic package and a manufacturing method of the electronic package. An electrical bridge die having a wiring portion is disposed on one side of a circuit structure, and a plurality of electronic components are disposed on the other side of the circuit structure. The wiring portion includes at least one magnetic layer and a coil inductor formed on the magnetic layer. The electrical bridge die is served as a power management IC and is integrated into the electronic package. Therefore, the power delivery distance to each of the plurality of electronic components can be reduced, effectively improving the performance of the electronic package.

### BACKGROUND

### 1. Technical Field

The present disclosure relates to a semiconductor packaging process, and more particularly, to an electronic package integrated with multiple chips and a manufacturing method thereof.

### 2. Description of Related Art

With the evolution of semiconductor packaging technology, in order to improve electrical functions and save packaging space, different packaging technologies have been developed. For example, in conjunction with the greatly increased number of input/output ports on various chips, integrated circuits with different functions are integrated into a single package structure. This packaging method can take advantage of the heterogeneous integration characteristics of System-in-Package (SiP) and can integrate electronic components, such as memories, central processing units, graphics processors, image application processors, etc., with different functions in a stacking design to achieve system integration. It is suitable to use in various thin and light electronic products.

FIG. 1 is a schematic perspective view showing a conventional semiconductor package 1 applied to a circuit board 6. As shown in FIG. 1, the circuit board 6 is equipped with at least one power management integrated circuit (power management IC) 60, a capacitor 61, and inductors 62, which together form a voltage regulator module (VRM) 6a.

However, in the conventional semiconductor package 1, the power is supplied by the voltage regulator module 6a. Consequently, a fixed distance is maintained between the semiconductor package 1 and the power management IC 60, resulting in the power management IC 60 supplying power to the semiconductor package 1 over an excessively long distance (e.g., long circuit 63). This causes prolonged delay times, making it challenging to improve the performance of the semiconductor package 1.

Moreover, the individual components of the voltage regulator module 6a, such as the power management IC 60, the capacitor 61, and the inductors 62, are independently mounted on the circuit board 6. As a result, these individual components occupy a certain amount of space on the circuit board 6, making it difficult to reduce the overall size of the circuit board 6. Consequently, the end product struggles to meet the requirements for miniaturization.

Therefore, overcoming the aforementioned drawbacks of the prior art has become an urgent issue to address.

### SUMMARY

In view of the aforementioned shortcomings of the prior art, the present disclosure provides an electronic package, which comprises: a circuit structure; an electrical bridge die having a wiring portion, bonded to a side of the circuit structure, and electrically connected to the circuit structure, wherein the wiring portion comprises a magnetic layer and a coil inductor formed on the magnetic layer; and a plurality of electronic components bonded to the other side of the circuit structure, and electrically connected to the circuit structure, wherein the plurality of electronic components are electrically connected to the electrical bridge die via the circuit structure.

The present disclosure further provides a method of manufacturing an electronic package, and the method comprises: providing an electrical bridge die having a wiring portion, wherein the wiring portion comprises a magnetic layer and a coil inductor formed on the magnetic layer; bonding the electrical bridge die to a side of a circuit structure and electrically connecting the electrical bridge die to the circuit structure; and bonding a plurality of electronic components to the other side of the circuit structure and electrically connecting the plurality of electronic components to the circuit structure, wherein the plurality of electronic components are electrically connected to the electrical bridge die via the circuit structure.

In the aforementioned electronic package and method, the present disclosure further comprises: disposing an interposing component on the side of the circuit structure, wherein the plurality of electronic components are electrically connected to the interposing component via the circuit structure. For example, the interposing component has a plurality of penetrating conductive vias.

In the aforementioned electronic package and method, the coil inductor has a first inductive segment and a second inductive segment respectively disposed on opposite sides of the magnetic layer, wherein the first inductive segment and the second inductive segment are connected to each other via a plurality of inductive pillars to surround the magnetic layer to form the coil inductor.

In the aforementioned electronic package and method, the electrical bridge die further comprises a semiconductor substrate having a plurality of conductive vias, wherein the wiring portion is formed on the semiconductor substrate and electrically connected to the plurality of conductive vias.

It can be seen from the above that, in the electronic package and the manufacturing method thereof of the present disclosure, the magnetic layer is formed within the electrical bridge die to form a coil inductor around the magnetic layer. This design enables the electrical bridge die to serve as a power management IC or an integrated voltage regulator, which is embedded within the electronic package. As a result, the power delivery distance to each of the electronic components is reduced. Therefore, compared to the prior art, the power delivery distance required by the electronic package of the present disclosure is shortened, effectively reducing delay time and improving the performance of the electronic package.

In addition, the electrical bridge die is integrated into the electronic package as a power management IC or an integrated voltage regulator. This integration reduces the area occupied on the wiring carrier, thereby decreasing the volume of the wiring carrier. As a result, compared to the prior art, the electronic package of the present disclosure enables a reduction in the size of the circuit board, allowing the end product to meet the demand for miniaturization.

### BRIEF DESCRIPTION OF THE DRAWINGS

FIG. 1 is a schematic perspective view showing a conventional semiconductor package applied to a circuit board.

FIG. 2A to FIG. 2D are schematic cross-sectional views illustrating a method of manufacturing an electrical bridge die according to the present disclosure.

FIG. 2E is a schematic partial top view of FIG. 2D.

FIG. 3A to FIG. 3F are schematic cross-sectional views illustrating a method of manufacturing an electronic package according to the present disclosure.

FIG. 4 is a schematic cross-sectional view illustrating an application of FIG. 3F.

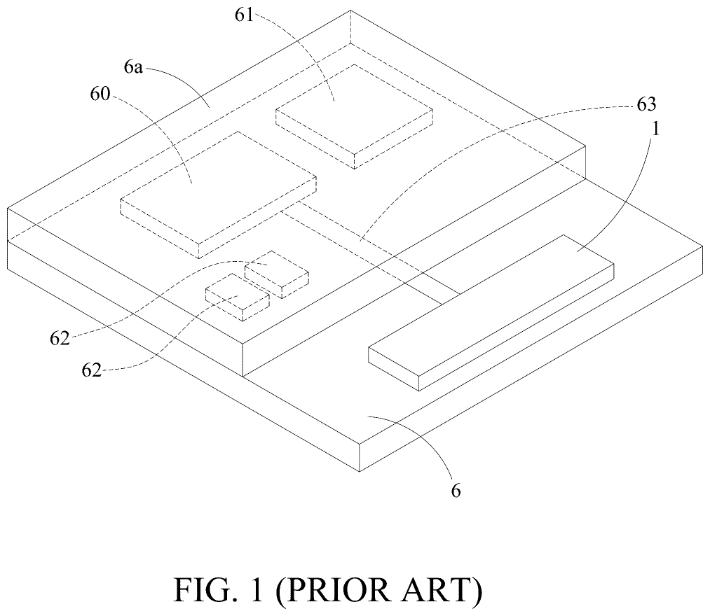

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

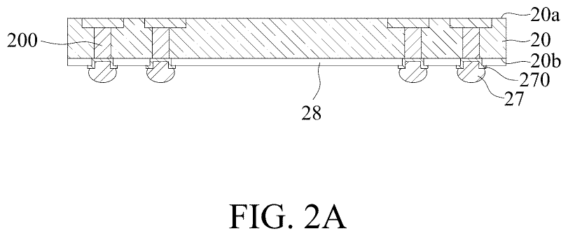

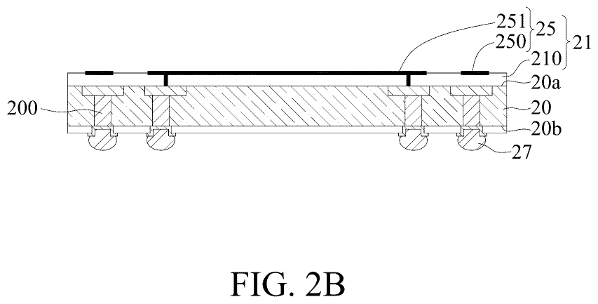

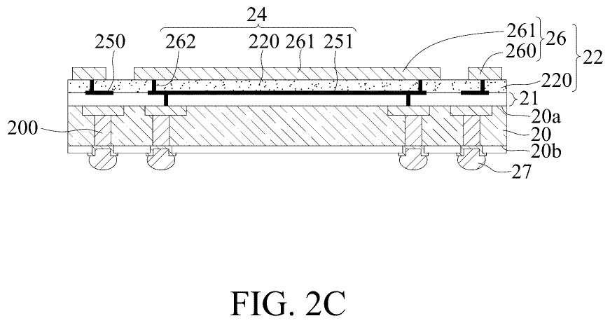

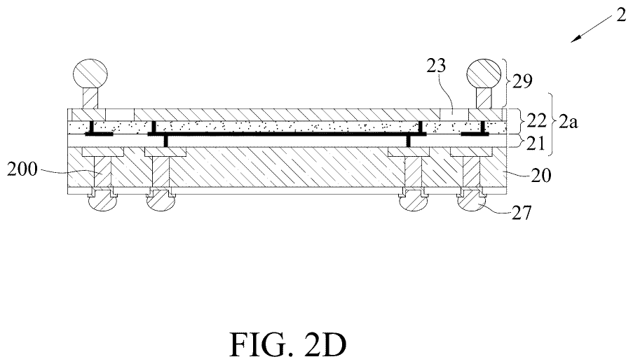

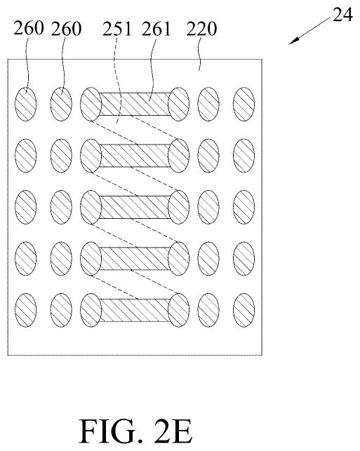

FIG. 2A to FIG. 2D are schematic cross-sectional views illustrating a method of manufacturing an electrical bridge die 2 according to the present disclosure. In one embodiment, the electrical bridge die 2 is served as a power management IC or an integrated voltage regulator (IVR).

As shown in FIG. 2A, a semiconductor substrate 20 is provided and has a first side 20a, a second side 20b opposite to the first side 20a, and a plurality of conductive vias 200 (such as conductive through-silicon vias [TSVs]) connecting the first side 20a and the second side 20b. One end surface of each of the conductive vias 200 is exposed from the first side 20a, and the other end surface of each of the conductive vias 200 is bonded to a conductive bump 27.

In one embodiment, the conductive bumps 27 consist of copper pillars and/or solder balls and are bonded to the conductive vias 200 through an under-bump metallization (UBM) layer 270. For example, a protective layer 28 to which the conductive vias 200 are exposed from can first be formed on the second side 20b of the semiconductor substrate 20. Subsequently, the under-bump metallization layer 270 is formed on the end surfaces of the conductive vias 200. The conductive bumps 27 are then formed on the under-bump metallization layer 270, such that the conductive bumps 27 protrude from the second side 20b of the semiconductor substrate 20.

As shown in FIG. 2B, a first wiring structure 21 is formed on the first side 20a of the semiconductor substrate 20 and is electrically connected to the conductive vias 200.

In one embodiment, the first wiring structure 21 comprises an insulating layer 210 and a first conductive layer 25 formed on the insulating layer 210 and electrically connected to the conductive vias 200, following redistribution layer (RDL) specifications. For example, the first conductive layer 25 is made of copper, and the insulating layer 210 is made of polybenzoxazole (PBO), polyimide (PI), prepreg (PP), or other dielectric materials.

Moreover, the first conductive layer 25 has a first circuit segment 250 and a first inductive segment 251.

As shown in FIG. 2C, a second wiring structure 22 is formed on the first wiring structure 21 and is electrically connected to the first wiring structure 21.

In one embodiment, the second wiring structure 22 comprises a magnetic layer 220 and a second conductive layer 26 formed on the magnetic layer 220 and electrically connected to the first conductive layer 25. For example, the second conductive layer 26 is made of copper, and the magnetic layer 220 is made of magnetic epoxy molding compound (EMC), magnetic polyimide (PI), or other magnetic dielectric materials.

Furthermore, the second conductive layer 26 has a second circuit segment 260 electrically connected to the first circuit segment 250, and a second inductive segment 261 corresponding to the first inductive segment 251. For example, the first inductive segment 251 and the second inductive segment 261 are connected to each other via a plurality of inductive pillars 262 to form a coil. This coil, in combination with the magnetic layer 220, constitutes a coil inductor 24, as shown in FIG. 2E.

As shown in FIG. 2D, a protective layer 23 is formed on the second wiring structure 22, and the second circuit segment 260 of the second conductive layer 26 is exposed from the protective layer 23 for bonding with conductive bumps 29, wherein the first wiring structure 21 and the second wiring structure 22 can be regarded as a wiring portion 2a.

In one embodiment, the conductive bumps 29 consist of copper pillars and/or solder balls. It should be understood that the number of layers in the wiring portion 2a can be designed according to requirements and is not limited to the above.

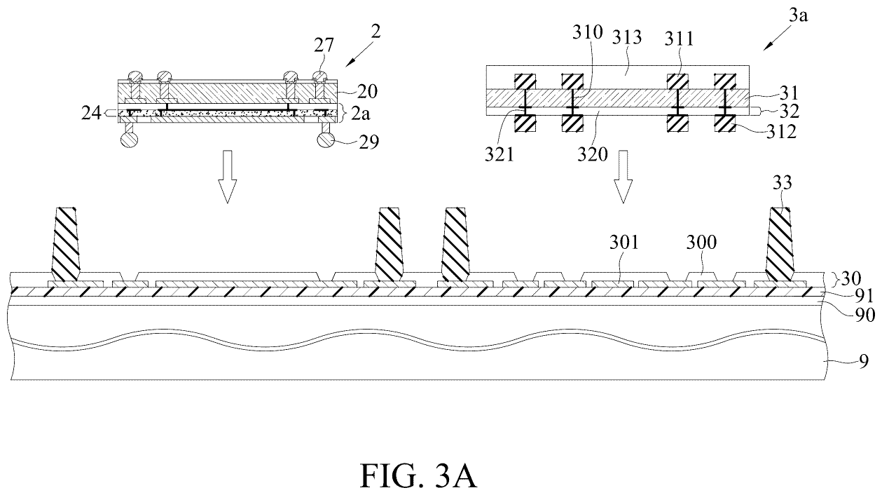

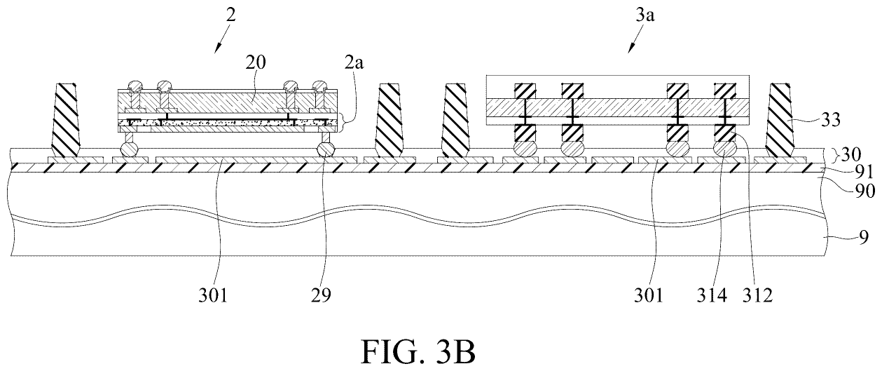

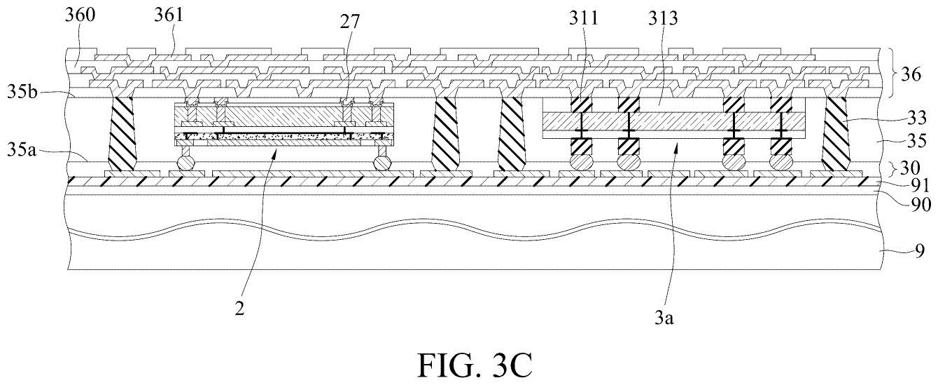

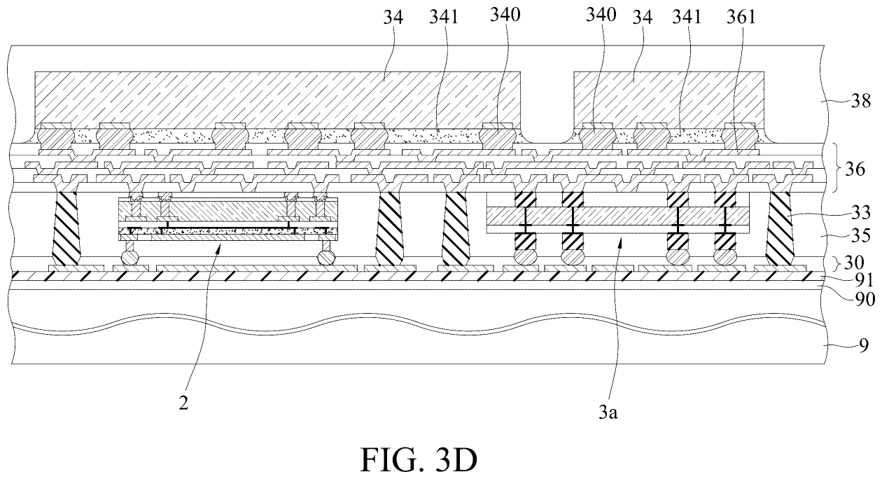

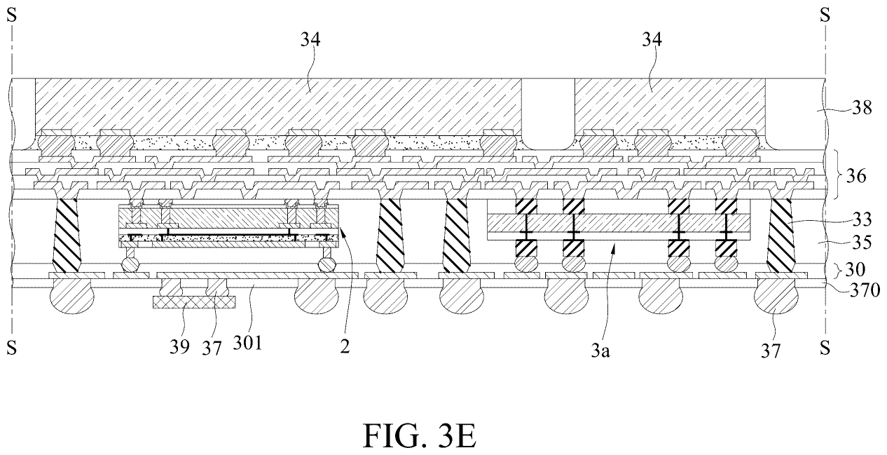

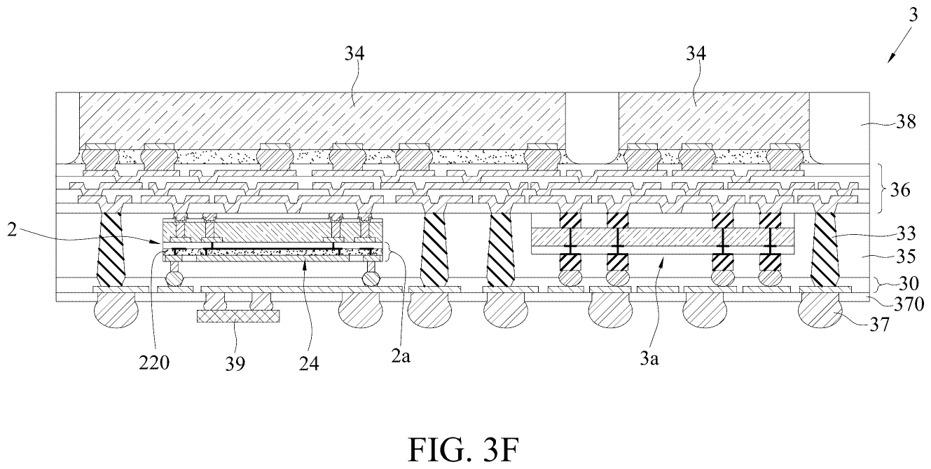

FIG. 3A to FIG. 3F are schematic cross-sectional views illustrating a method of manufacturing an electronic package 3 according to the present disclosure.

As shown in FIG. 3A, at least one interposing component 3a, at least one electrical bridge die 2 shown in FIG. 2D, and a carrier structure 30 disposed on a carrier 9 are provided. Additionally, a plurality of conductive pillars 33 are formed on the carrier structure 30.

In one embodiment, the interposing component 3a includes an interposer 31, a circuit portion 32, a plurality of first conductors 311 formed on the interposer 31, and a plurality of second conductors 312 formed on the circuit portion 32 and electrically connected to the circuit portion 32, wherein the plurality of first conductors 311 are encapsulated by a protective film 313.

The interposer 31 is made of a silicon-based material and has a plurality of conductive vias 310 (such as conductive through-silicon vias [TSVs]) penetrating through the interposer 31 and electrically connected to the circuit portion 32 and the plurality of first conductors 311.

The circuit portion 32 includes at least one passivation layer 320 and conductive traces 321 bonded to the passivation layer 320. The conductive traces 321 are electrically connected to the conductive vias 310 and the plurality of second conductors 312. It should be understood that the configurations involving the interposing component 3a are varied and not specifically restricted.

The first conductors 311 and the second conductors 312 are metal pillars such as copper pillars. The protective film 313 is an insulating film or is made of polyimide (PI). The first conductors 311 are not exposed from the protective film 313.

In addition, the carrier structure 30 includes at least one insulating layer 300 and at least one wiring layer 301 formed on the insulating layer 300. For example, the wiring layer 301 is made of copper, and the insulating layer 300 is made of polybenzoxazole (PBO), polyimide (PI), prepreg (PP), or other dielectric materials.

Moreover, the carrier 9 is, for example, a board made of a semiconductor material (such as silicon or glass), on which a release layer 90 and an adhesive layer 91 are sequentially formed by coating, and the carrier structure 30 is disposed on the adhesive layer 91.

Furthermore, the conductive pillars 33 are disposed on the wiring layer 301 and are electrically connected to the wiring layer 301. The conductive pillars 33 are made of a metal material such as copper or a solder material.

As shown in FIG. 3B, the electrical bridge die 2 and the interposing component 3a are disposed on the carrier structure 30.

In one embodiment, the electrical bridge die 2 is disposed on the carrier structure 30 via its wiring portion 2a, and the conductive bumps 29 are electrically connected to the wiring layer 301. Additionally, the interposing component 3a is bonded to the carrier structure 30 via its second conductors 312 using a solder material 314, and the second conductors 312 are electrically connected to the wiring layer 301.

As shown in FIG. 3C, an encapsulation layer 35 is formed on the carrier structure 30 and encapsulates the electrical bridge die 2, the interposing component 3a, and the conductive pillars 33, wherein the encapsulation layer 35 has a first surface 35a and a second surface 35b opposite to the first surface 35a, and the encapsulation layer 35 is bonded to the carrier structure 30 via the first surface 35a. Then, a circuit structure 36 is formed on the second surface 35b of the encapsulation layer 35 and is electrically connected to the conductive pillars 33, the electrical bridge die 2, and the interposing component 3a.

In one embodiment, the encapsulation layer 35 is made of an insulating material, such as epoxy molding colloid or epoxy molding compound. The encapsulation layer 35 can be formed on the carrier structure 30 by lamination or molding.

In addition, through a planarization process, the second surface 35b of the encapsulation layer 35 is flush with the end surfaces of the conductive pillars 33, the surfaces of the conductive bumps 27, the surface of the protective film 313, and the surfaces of the first conductors 311, such that the conductive pillars 33, the conductive bumps 27, the protective film 313, and the first conductors 311 are exposed from the second surface 35b of the encapsulation layer 35. For example, the planarization process can be performed by grinding to remove portions of the materials from the conductive pillars 33, the conductive bumps 27, the protective film 313, the first conductors 311, and the encapsulation layer 35.

Moreover, the circuit structure 36 includes a plurality of dielectric layers 360 and a plurality of circuit layers 361 formed on the dielectric layers 360, following redistribution layer (RDL) specifications. The outermost dielectric layer 360 can be served as a solder-resist layer, and the outermost circuit layer 361 is exposed from the solder-resist layer. Alternatively, the circuit structure 36 may also comprise only a single dielectric layer 360 and a single circuit layer 361.

Furthermore, the circuit layers 361 are made of copper, and the dielectric layers 360 are made of polybenzoxazole (PBO), polyimide (PI), prepreg (PP), or other dielectric materials.

As shown in FIG. 3D, a plurality of electronic components 34 are disposed on the outermost circuit layer 361 of the circuit structure 36, wherein the electronic components 34 can be electrically connected to each other via the circuit structure 36 and the electrical bridge die 2, and then the electronic components 34 are encapsulated by a packaging layer 38.

Each of the electronic components 34 is an active element, a passive element, or a combination of the active element and the passive element. The active element is, for example, a semiconductor chip. The passive element is, for example, a resistor, a capacitor, or an inductor. For example, the interposing component 3a can also be served as an electrical bridge die, so that the electronic components 34 are electrically connected to each other via the interposing component 3a.

In one embodiment, the electronic components 34 are semiconductor chips, which are disposed on the circuit layer 361 via a plurality of conductive bumps 340 (made of such as a solder material) in a flip-chip manner and are electrically connected to the circuit layer 361, wherein the conductive bumps 340 are encapsulated by an underfill 341; alternatively, the electronic components 34 can be electrically connected to the circuit layer 361 via a plurality of bonding wires (not shown) in a wire-bonding manner; or, the electronic components 34 can be electrically connected to the circuit layer 361 via a conductive material such as conductive glue or solder (not shown). However, the methods for electrically connecting the electronic components 34 to the circuit layer 361 are not limited to those described above.

In addition, the packaging layer 38 is made of polyimide (PI), dry film, epoxy molding colloid, epoxy molding compound, or other insulating materials. The packaging layer 38 can be formed on the circuit structure 36 by lamination or molding. It can be understood that the packaging layer 38 and the encapsulation layer 35 can be made from the same material or different materials.

Moreover, the packaging layer 38 encapsulates the underfill 341. However, the underfill 341 may not be formed, in which case the packaging layer 38 directly encapsulates the conductive bumps 340.

As shown in FIG. 3E, the carrier 9 and the release layer 90 and the adhesive layer 91 thereon are removed to expose the carrier structure 30.

In one embodiment, a plurality of conductive components 37 such as solder balls are formed on the carrier structure 30, and the conductive components 37 are electrically connected to the wiring layer 301. For example, an insulating protective layer 370 such as a solder-resist layer may first be formed on the carrier structure 30. The insulating protective layer 370 is formed with a plurality of openings that expose the wiring layer 301, allowing the conductive components 37 to bond in accordance with C4 bump specifications (C4 stands for Controlled Collapse Chip Connection).

Furthermore, at least one auxiliary component 39 may be disposed on some of the conductive components 37 on the carrier structure 30, and the auxiliary component 39 is electrically connected to the wiring layer 301 via the conductive components 37. For example, the auxiliary component 39 is an active element, a passive element, or a combination of the active element and the passive element. The active element is, for example, a semiconductor chip. The passive element is, for example, a resistor, a capacitor, or an inductor.

Additionally, a planarization process, such as grinding, can be used to remove part of the material of the packaging layer 38. Consequently, the upper surface of the packaging layer 38 is flush with the upper surfaces of the electronic components 34, and the electronic components 34 are exposed from the packaging layer 38.

As shown in FIG. 3F, a singulation process is performed along cutting paths S shown in FIG. 3E to obtain the electronic package 3.

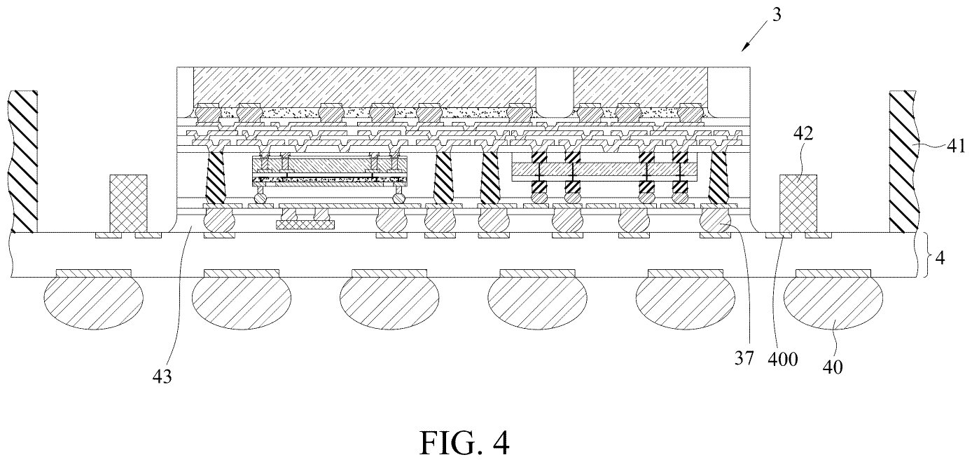

In one embodiment, the electronic package 3 can be disposed on the upper side of a wiring carrier 4 via the conductive components 37, as shown in FIG. 4. Subsequently, an underfill 43 is applied to encapsulate the conductive components 37. For example, the wiring carrier 4 is an organic material board (such as a package substrate having a core layer and a circuit portion, or a coreless package substrate having a circuit portion), or an inorganic material board (such as a silicon board).

Moreover, at least one heat sink 41 and/or at least one electrical functional component 42 can be disposed on the upper side of the wiring carrier 4 according to requirements. The lower side of the wiring carrier 4 can be connected to an electronic device (not shown) such as a circuit board via a plurality of solder balls 40, and the wiring carrier 4 is electrically connected to the electronic device.

Furthermore, the electrical functional component 42 is an active element, a passive element, or a combination of the active element and the passive element. The electrical functional component 42 is electrically connected to electrical contacts 400 of the wiring carrier 4. The active element is, for example, a semiconductor chip. The passive element is, for example, a resistor, a capacitor, or an inductor.

Therefore, the present disclosure forms the magnetic layer 220 within the electrical bridge die 2, allowing the first inductive segment 251 and the second inductive segment 261 to surround the magnetic layer 220, thereby forming the coil inductor 24. This design enables the electrical bridge die 2 to serve as a power management IC or an integrated voltage regulator (IVR), which is embedded within the electronic package 3. As a result, the power delivery distance to each of the electronic components 34 is reduced. Thus, compared to the prior art, the power delivery distance required by the electronic package 3 of the present disclosure is shortened, effectively reducing delay time and improving the performance of the electronic package 3.

In addition, the electrical bridge die 2 is integrated into the electronic package 3 as a power management IC or an integrated voltage regulator (IVR). This integration reduces the area occupied on the wiring carrier 4, thereby decreasing the volume of the wiring carrier 4. As a result, compared to the prior art, the electronic package 3 of the present disclosure enables a reduction in the size of the circuit board, allowing the end product to meet the demand for miniaturization.

The present disclosure provides an electronic package 3, which comprises: a circuit structure 36 having opposite sides, an electrical bridge die 2 having a wiring portion 2a, and a plurality of electronic components 34.

The electrical bridge die 2 is bonded to a side of the circuit structure 36 and is electrically connected to the circuit structure 36, wherein the wiring portion 2a includes at least one magnetic layer 220 and a coil inductor 24 formed on the magnetic layer 220.

The electronic components 34 are bonded to the other side of the circuit structure 36 and are electrically connected to the circuit structure 36, and the plurality of electronic components 34 are electrically connected to each other via the circuit structure 36 and the electrical bridge die 2.

In one embodiment, an interposing component 3a is disposed on the side of the circuit structure 36, and the plurality of electronic components 34 are electrically connected to the interposing component 3a via the circuit structure 36. For example, the interposing component 3a has penetrating conductive vias 310.

In one embodiment, the coil inductor 24 has a first inductive segment 251 and a second inductive segment 261 respectively disposed on opposite sides of the magnetic layer 220, and the first inductive segment 251 and the second inductive segment 261 are connected to each other via a plurality of inductive pillars 262 to surround the magnetic layer 220 to form the coil inductor 24.

In one embodiment, the electrical bridge die 2 further includes a semiconductor substrate 20 having a plurality of conductive vias 200, wherein the wiring portion 2a is formed on the semiconductor substrate 20 and is electrically connected to the conductive vias 200.

To sum up, in the electronic package and the manufacturing method thereof of the present disclosure, the magnetic layer is formed within the electrical bridge die, allowing the first inductive segment and the second inductive segment to surround the magnetic layer, thereby forming a coil inductor. This design enables the electrical bridge die to serve as a power management IC or an integrated voltage regulator, which is embedded within the electronic package. As a result, the power delivery distance to each of the electronic components is reduced. Thus, the power delivery distance required by the electronic package of the present disclosure is shortened, effectively reducing delay time and improving the performance of the electronic package.

Moreover, the electrical bridge die is integrated into the electronic package as a power management IC or an integrated voltage regulator. This integration reduces the area occupied on the wiring carrier, thereby decreasing the volume of the wiring carrier. As a result, the electronic package of the present disclosure enables a reduction in the size of the circuit board, allowing the end product to meet the demand for miniaturization.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a circuit structure;
an electrical bridge die having a wiring portion, bonded to a side of the circuit structure, and electrically connected to the circuit structure, wherein the wiring portion comprises a magnetic layer and a coil inductor formed on the magnetic layer; and
a plurality of electronic components bonded to the other side of the circuit structure, and electrically connected to the circuit structure, wherein the plurality of electronic components are electrically connected to the electrical bridge die via the circuit structure.

2. The electronic package of claim 1, further comprising: an interposing component disposed on the side of the circuit structure, wherein the plurality of electronic components are electrically connected to the interposing component via the circuit structure.

3. The electronic package of claim 2, wherein the interposing component has a plurality of penetrating conductive vias.

4. The electronic package of claim 1, wherein the coil inductor has a first inductive segment and a second inductive segment respectively disposed on opposite sides of the magnetic layer, wherein the first inductive segment and the second inductive segment are connected to each other via a plurality of inductive pillars to surround the magnetic layer to form the coil inductor.

5. The electronic package of claim 1, wherein the electrical bridge die further comprises a semiconductor substrate having a plurality of conductive vias, wherein the wiring portion is formed on the semiconductor substrate and electrically connected to the plurality of conductive vias.

6. A method of manufacturing an electronic package, comprising:
providing an electrical bridge die having a wiring portion, wherein the wiring portion comprises a magnetic layer and a coil inductor formed on the magnetic layer;
bonding the electrical bridge die to a side of a circuit structure and electrically connecting the electrical bridge die to the circuit structure; and
bonding a plurality of electronic components to the other side of the circuit structure and electrically connecting the plurality of electronic components to the circuit structure, wherein the plurality of electronic components are electrically connected to the electrical bridge die via the circuit structure.

7. The method of claim 6, further comprising: disposing an interposing component on the side of the circuit structure, wherein the plurality of electronic components are electrically connected to the interposing component via the circuit structure.

8. The method of claim 7, wherein the interposing component has a plurality of penetrating conductive vias.

9. The method of claim 6, wherein the coil inductor has a first inductive segment and a second inductive segment respectively disposed on opposite sides of the magnetic layer, wherein the first inductive segment and the second inductive segment are connected to each other via a plurality of inductive pillars to surround the magnetic layer to form the coil inductor.

10. The method of claim 6, wherein the electrical bridge die further comprises a semiconductor substrate having a plurality of conductive vias, wherein the wiring portion is formed on the semiconductor substrate and electrically connected to the plurality of conductive vias.
